(19) United States
(12) Patent Application Publication
(10) Pub. No.: US 2016/0105976 A1
(43) Pub. Date: Apr. 14, 2016

(54) ELECTRONIC DEVICE ENCLOSURE

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: YU-MING XIAO, Wuhan (CN); LIANG-CHIN WANG, New Taipei (TW); ZAN LI, Wuhan (CN); TIAN ZHANG, Wuhan (CN)

(21) Appl. No.: 14/526,230

(22) Filed: Oct. 28, 2014

(30) Foreign Application Priority Data
Oct. 14, 2014 (CN) 201410540561.0

(51) Int. Cl. H05K 5/00; H05K 5/02

(52) U.S. Cl. CPC H05K 5/0004; H05K 5/0217

(57) ABSTRACT

An electronic device enclosure includes a panel, a basic frame, a first frame, a second frame, and a sleeve. Both the first frame and the second frame are located between the panel and the basic frame. An inner space is defined by the panel, the basic frame, the first frame, and the second frame. A first inlet is surrounded by the panel, the first frame, and the basic frame and a second inlet is surrounded by the panel, the second frame, and the basic frame. Both the first inlet and second inlet communicate with the inner space. The sleeve covers outside the first frame and the second frame to shield the first inlet and the second inlet.

### FIELD

The subject matter herein generally relates to electronic device enclosures.

### BACKGROUND

A variety of electronic components, such as hard disk drives and power source modules, are secured inside an electronic device enclosure. The electronic device enclosure is helpful for protecting the internal electronic components.

### BRIEF DESCRIPTION OF THE DRAWINGS

Implementations of the present technology will now be described, by way of example only, with reference to the attached figures.

FIG. 1 is an exploded view of an electronic device enclosure in an embodiment.

FIG. 2 is an assembled view of the electronic device enclosure of FIG. 1 with the sleeve omitted.

FIG. 3 is another assembled view of FIG. 1, with the sleeve partially shielding the first inlet, the second inlet, the third inlet, and the fourth inlet.

FIG. 4 is another assembled view of FIG. 1, with the sleeve completely shielding the first inlet, the second inlet, the third inlet, and the fourth inlet.

FIG. 5 is another assembled view of the electronic device enclosure in another embodiment, with the sleeve completely shielding the fourth inlet.

FIG. 6 is another assembled view of FIG. 5, with the sleeve completely shielding the second inlet and the fourth inlet.

FIG. 7 is another assembled view of FIG. 5, with the sleeve completely shielding the second inlet, the third inlet, and the fourth inlet.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

The present disclosure is described in relation to an electronic device enclosure. The electronic device enclosure includes a panel, a basic frame, a first frame, a second frame, and a sleeve. Both the first frame and the second frame are located between the panel and the basic frame. An inner space is defined by the panel, the basic frame, the first frame, and the second frame. A first inlet is surrounded by the panel, the first frame, and the basic frame and a second inlet is surrounded by the panel, the second frame, and the basic frame. Both the first inlet and second inlet communicate with the inner space. The sleeve covers the outside of the first frame and the second frame to shield the first inlet and the second inlet.

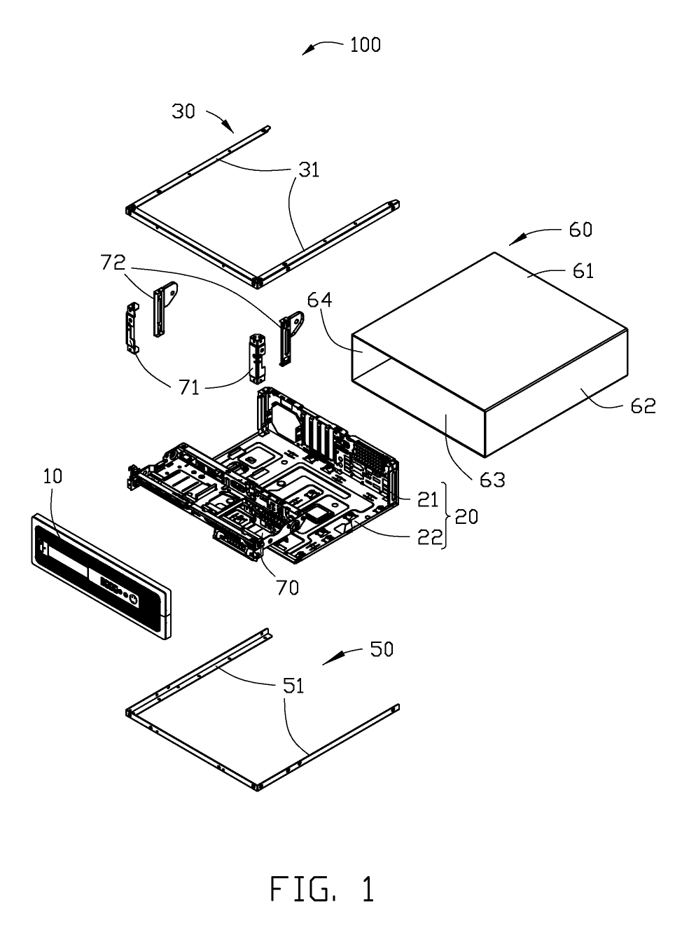

FIG. 1 illustrates that an electronic device enclosure 100 for accommodating a plurality of electronic components (not shown) includes a panel 10, a basic frame 20, a first frame 30, a second frame 50, and a sleeve 60. Both the first frame 30 and the second frame 50 are connected between the panel 10 and the basic frame 20 and form the main framework of the electronic device enclosure 100. The first frame 30 and the second frame 50 can be received in sleeve 60.

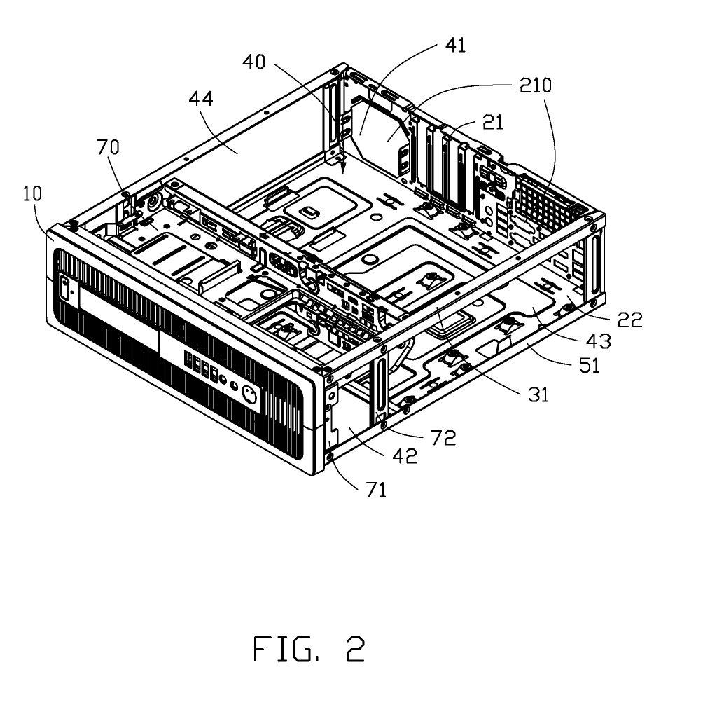

In one embodiment, the basic frame 20 is substantially L-shaped and includes a vertical portion 21 and a horizontal portion 22. The vertical portion 21 is substantially parallel to the panel 10, and the horizontal portion 22 is substantially perpendicular to the panel 10. The plurality of electronic components, such as a power supply unit and a dissipating fan, can be secured on the horizontal portion 22. Several slots 210 (see FIG. 2) are defined in the vertical portion 21 and correspond to the electronic components.

FIGS. 1-2 illustrate that the first frame 30 is substantially U-shaped and includes two parallel first arms 31. The second frame 50 is also substantially U-shaped and includes two parallel second arms 51. In an embodiment, the first frame 30 can be the same as the second frame 50.

The first frame 30 and the second frame 50 can be coupled to the panel 10 and the basic frame 20 by a well known manner, such as screws or rivets. Opposite ends of each first arm 31 and opposite ends of each second arm 51 abut the panel 10 and the vertical portion 21. Therein, the two first arms 31 are located at a first plane, the two second arms 51 are located at a second plane, one of the two first arms 31 and one of the two second arms 51 are located at a third plane, and another of the two first arms 31 and another of the two second arms 51 are located at a fourth plane. The first plane is substantially parallel with the second plane and perpendicular to the third plane, and the fourth plane is substantially parallel with the third plane and perpendicular to the second plane. An inner space 40, which is configured to accommodate the electronic components, is defined by the panel 10, the basic frame 20, the first frame 30, and the second frame 50.

A first inlet 41 is surrounded by the panel 10, two first arms 31 of the first frame 30, and the vertical portion 21. The first inlet 41 communicates with the inner space 40 and is positioned on the first plane. A second inlet 42 is surrounded by the panel 10, two second arms 51 of the second frame 50, and the horizontal portion 22. The second inlet 42 communicates with the inner space 40 and is positioned on the second plane. The first inlet 41 and the second inlet 42 are on the opposite sides of the electronic device enclosure 100.

A third inlet 43 is surrounded by the panel 10, one of the first arms 31, one of the second arms 51, and the vertical portion 21. The third inlet 43 communicates with the inner space 40 and is positioned on the third plane. A fourth inlet 44 is surrounded by the panel 10, another of the first arms 31, another of the second arms 51, and the vertical portion 21. The fourth inlet 44 communicates with the inner space 40 and is positioned on the fourth plane. The third inlet 43 and the fourth inlet 44 are on the opposite sides of the electronic device enclosure 100.

The electronic device enclosure 100 further includes a bracket 70, two first support members 71 and two second support members 72. The bracket 70, which is configured to accommodate the electronic components such as a hard disk drive and an optical drive, is supported and secured inside the inner space 40 by the first support members 71 and the second support members 72. Each of the first support members 71 and each of the second support members 72 are substantially parallel to the vertical portion 21. The first support members 71 and the second support members 72 are secured between the first frame 30 and the second frame 50. One of the first support members 71 and one of the second support members 72 are located at the third plane, and another of the first support members 71 and another of the second support members 72 are located at the fourth plane.

FIGS. 1-4 illustrate that the sleeve 60 includes a first portion 61, a second portion 62, a third portion 63, and a fourth portion 64. The sleeve 60 is configured to cover the first frame 30 and the second frame 50. Therein, the first inlet 41 is shielded by the first portion 61, the second inlet 42 is shielded by the third portion 63, the third inlet 43 is shielded by the second portion 62, and the fourth inlet 44 is shielded by the fourth portion 64. The inner space 40 is located inside the sleeve 60.

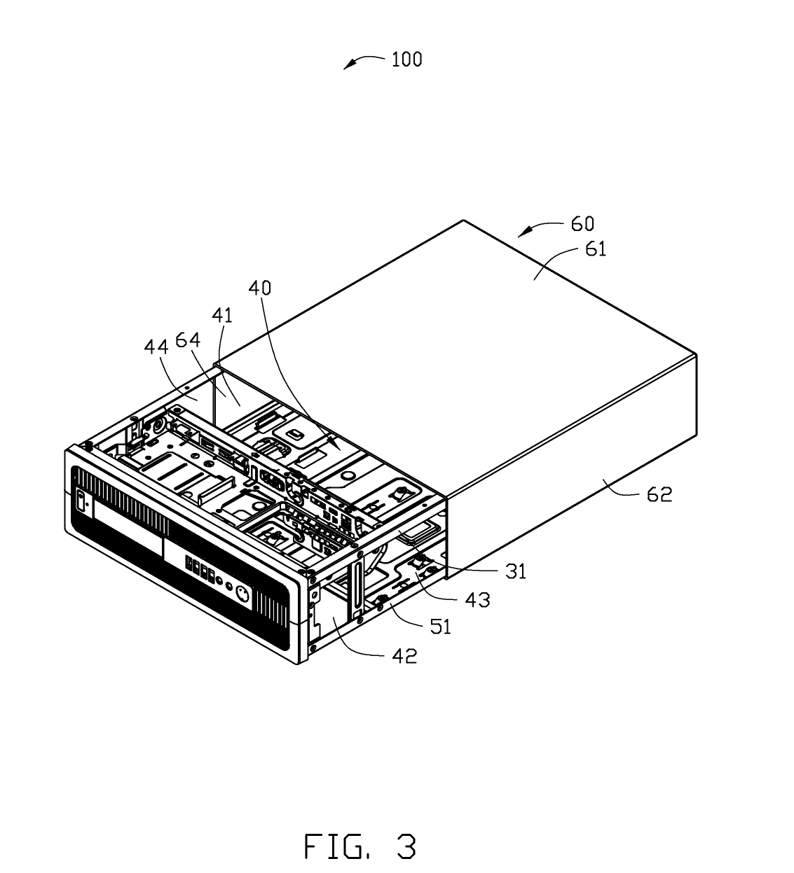

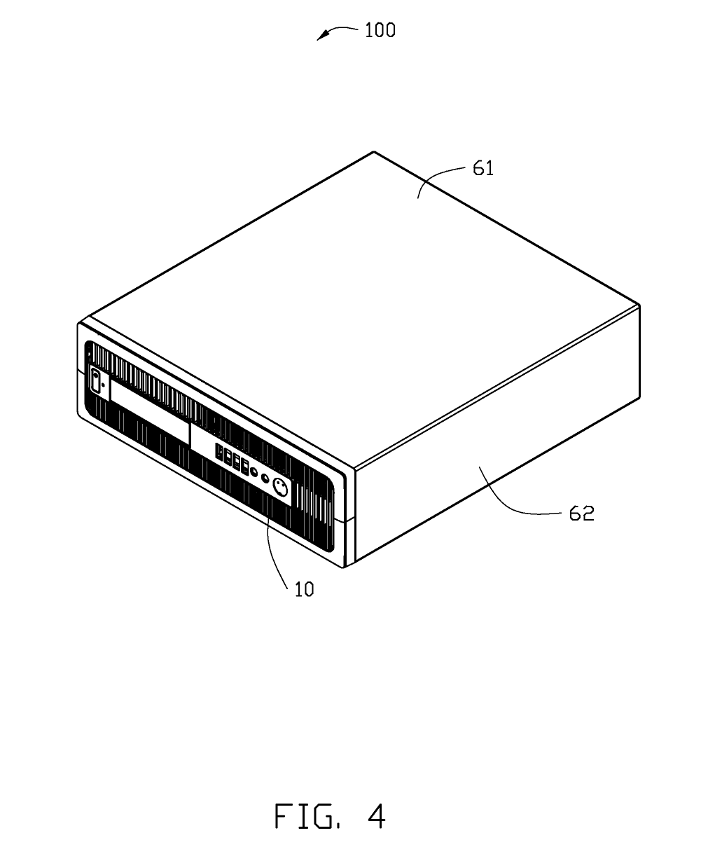

FIGS. 3-4 illustrate that in at least one embodiment, the sleeve 60 is integrally formed and covers the first frame 30 and the second frame 50 by interference fit.

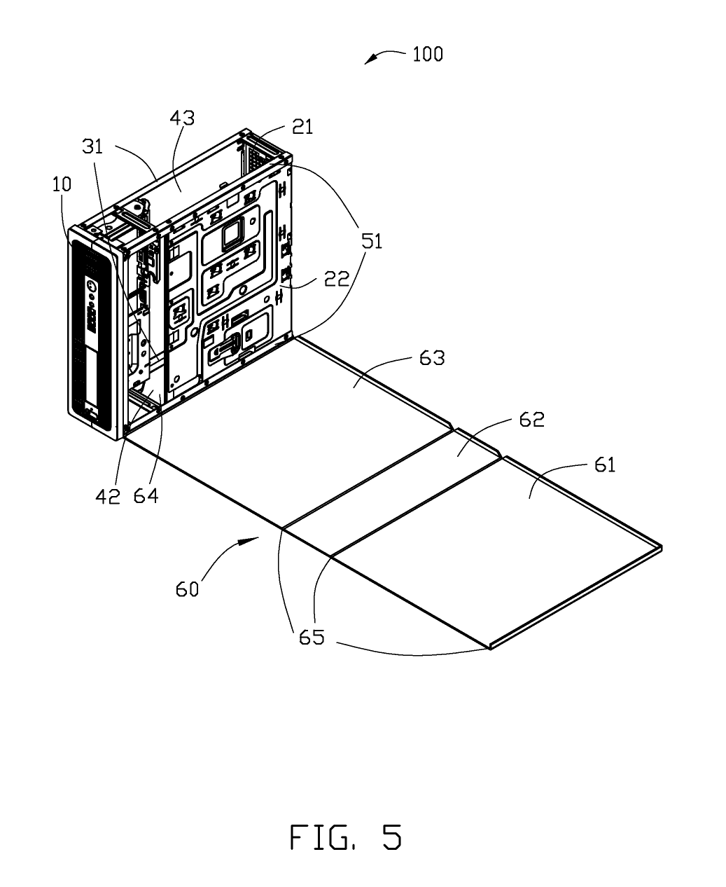

FIGS. 5-7 illustrate that in at least one embodiment, the second portion 62 pivots and is connected between the first portion 61 and the third portion 63, and the third portion 63 pivots and is connected between the second portion 62 and the fourth portion 64. The sleeve 60 is configured to stretch as a flat plate or be folded as a hollow sleeve. The sleeve 60 further includes several magnetic portions 65 corresponding to the first frame 30 and the second frame 50. Each of the magnetic portions 65 are configured to attach to each of the first arms 31 and each of the second arms 51.

FIG. 5 illustrates that in assembly, the first portion 61, the second portion 62, the third portion 63, and the fourth portion 64 are stretched as a flat plate. The fourth portion 64 is closed to the first frame 30 and the second frame 50 to shield the fourth inlet 44.

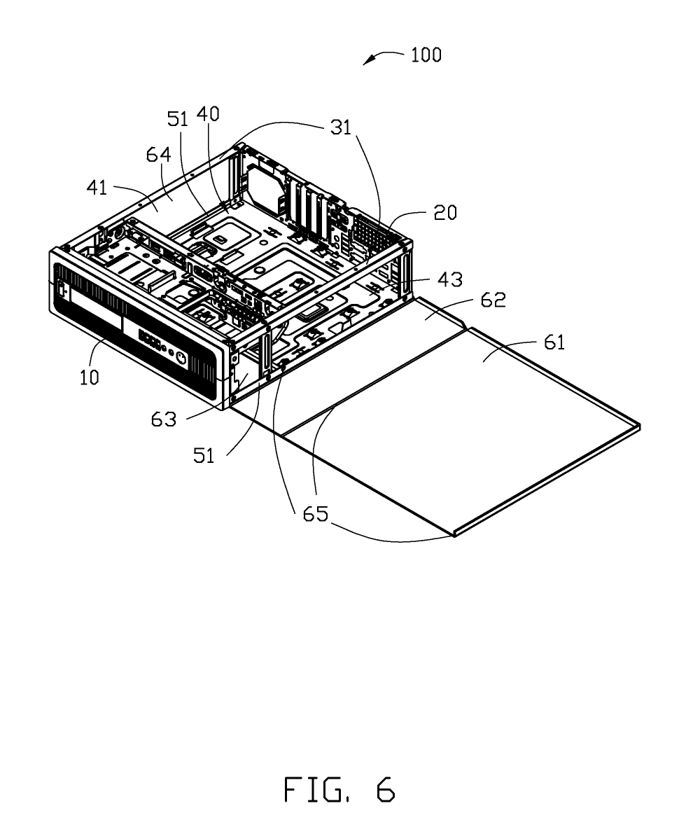

FIG. 6 illustrates that the third portion 63 is rotated relative to the fourth portion 64 to shield the second inlet 42.

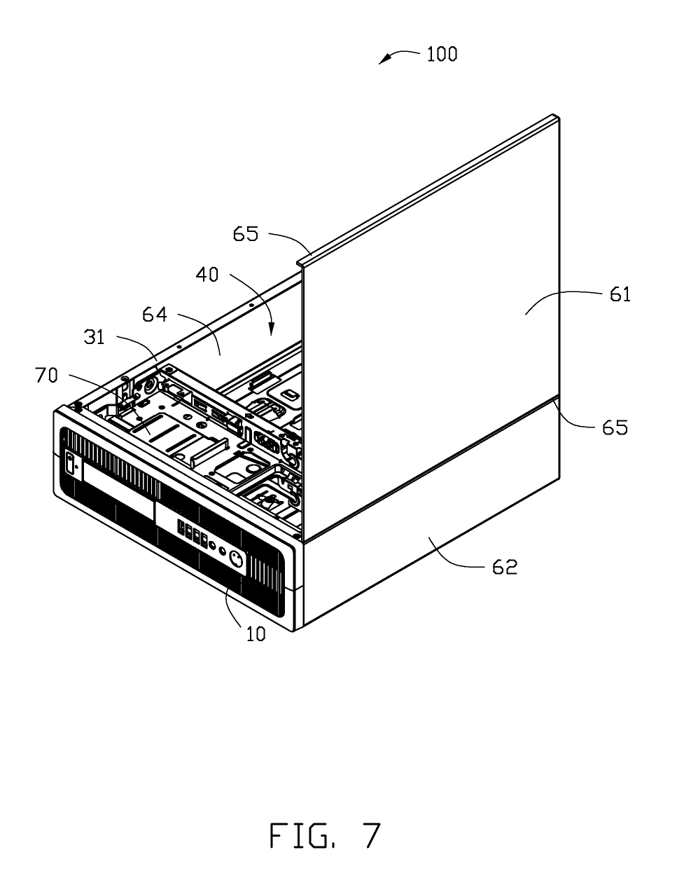

FIG. 7 illustrates that the second portion 62 is rotated relative to the third portion 63 to shield the third inlet 43.

Finally, the first portion 61 is rotated relative to the second portion 62 to shield the first inlet 41. Thereby, the first inlet 41, the second inlet 42, the third inlet 43, and the fourth inlet 44 are completely shielded by the sleeve 60. In that time, the sleeve 60 is secured to the first frame 30 and the second frame 50 by the magnetic portions 65.

The sleeve 60 is made of a non-metallic material. In one embodiment, the sleeve 60 is made of paperboard with aluminized paper on the inner surface and coated on the outer surface.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. An electronic device enclosure comprising:
a panel and a basic frame;
a first frame and a second frame located between the panel and the basic frame, and an inner space defined by the panel, the basic frame, the first frame, and the second frame;
a first inlet surrounded by the panel, the first frame, and the basic frame;
a second inlet surrounded by the panel, the second frame, and the basic frame; and
a sleeve covering the first frame and the second frame, thereby the first inlet and the second inlet shielded by the sleeve,
wherein both the first inlet and second inlet communicate with the inner space.

2. The electronic device enclosure of claim 1, wherein the first frame comprises two parallel first arms, each first arm abuts the panel and the basic frame for allowing the first inlet to be defined by the two first arms; the second frame comprises two parallel second arms, each second arm abuts the panel and the basic frame for allowing the second inlet to be defined by the two second arms.

3. The electronic device enclosure of claim 2, wherein the first inlet is positioned on a first plane, and the second inlet is positioned on a parallel second plane; the first inlet and second inlet are at opposite sides of the electronic device enclosure.

4. The electronic device enclosure of claim 3, wherein one of the two first arms and one of the two second arms are located at a third plane, another of the two first arms and another of the two second arms are located at a fourth plane; the third plane and fourth plane are substantially parallel to each other and substantially perpendicular to both the first plane and second plane.

5. The electronic device enclosure of claim 4, wherein a third inlet is defined between one of the two first arms and one of the two second arms and positioned on the third plane, a fourth inlet is defined between another of the two first arms and another of the two second arms and positioned on the fourth plane; both the third inlet and the fourth inlet communicate with the inner space and are shielded by the sleeve.

6. The electronic device enclosure of claim 5, wherein the sleeve comprises a first portion, a second portion, a third portion, and a fourth portion; when the sleeve is covered the first frame and the second frame, the first inlet is shielded by the first portion, the second inlet is shielded by the third portion, the third inlet is shielded by the second portion, and the fourth inlet is shielded by the fourth portion.

7. The electronic device enclosure of claim 6, wherein the second portion is pivotably connected between the first portion and the third portion, the third portion is pivotably connected between the second portion and the fourth portion.

8. The electronic device enclosure of claim 1, wherein the sleeve further comprises several magnetic portions corresponding to the first frame and the second frame, each of the magnetic portions is capable of attaching to each of the first frame and the second frame, thereby the sleeve being secured to the first frame and the second frame.

9. The electronic device enclosure of claim 1, wherein the sleeve is made of a non-metallic material.

10. The electronic device enclosure of claim 9, wherein the sleeve is made of paperboard with aluminized paper on the inner surface and coated on the outer surface.

11. An electronic device enclosure comprising:
a panel and a basic frame;
a first frame and a second frame both located between the panel and the basic frame, and an inner space defined by the panel, the basic frame, the first frame, and the second frame;
two first support members and two second support members secured between the first frame and the second frame; and
a bracket located in the inner space, configured to accommodate at least one electronic component, supported by the first support members and the second support members.

12. The electronic device enclosure of claim 11 further comprising a first inlet communicating the inner space, a second inlet communicating the inner space, and a sleeve covering the first frame and the second frame for shielding the first inlet and the second inlet; wherein, the first inlet is surrounded by the panel, the first frame, and the basic frame; the second inlet is surrounded by the panel, the second frame, and the basic frame.

13. The electronic device enclosure of claim 12, wherein the first frame comprises two parallel first arms, each first arm abuts the panel and the basic frame for allowing the first inlet to be defined by the two first arms; the second frame comprises two parallel second arms, each second arm abuts the panel and the basic frame for allowing the second inlet to be defined by the two second arms.

14. The electronic device enclosure of claim 13, wherein the first inlet is positioned on a first plane, and the second inlet is positioned on a parallel second plane; the first inlet and second inlet are at opposite sides of the electronic device enclosure.

15. The electronic device enclosure of claim 13, wherein one of the two first arms and one of the two second arms are located at a third plane and define a third inlet therebetween; another of the two first arms and another of the two second arms are located at a fourth plane and define a fourth inlet therebetween.

16. The electronic device enclosure of claim 15, wherein each of the first support members and each of the second support members are alternatively located at the third plane or the fourth plane.

17. The electronic device enclosure of claim 15, wherein both the third inlet and the fourth inlet communicate with the inner space and are shielded by the sleeve.

18. The electronic device enclosure of claim 12, wherein the sleeve comprises a first portion and a third portion; when the sleeve is covered the first frame and the second frame, the first inlet is shielded by the first portion, and the second inlet is shielded by the third portion.

19. The electronic device enclosure of claim 12, wherein the sleeve further comprises several magnetic portions corresponding to the first frame and the second frame, each of the magnetic portions is capable of attaching to each of the first frame and the second frame, thereby the sleeve being secured to the first frame and the second frame.

20. The electronic device enclosure of claim 12, wherein the sleeve is made of a non-metallic material.
